(19) United States
(12) Patent Application Publication
(10) Pub. No.: US 2009/0057755 A1
(43) Pub. Date: Mar. 5, 2009

(54) SPACER UNDERCUT FILLER, METHOD OF MANUFACTURE THEREOF AND ARTICLES COMPRISING THE SAME

(75) Inventors: Thomas W. Dyer, Pleasant Valley, NY (US); Oh-Jung Kwon, Hopewell Junction, NY (US); Nivo Rovedo, LaGrangeville, NY (US); O Sung Kwon, Wappingers Falls, NY (US); Bong-Seok Suh, Fishkill, NY (US)

Correspondence Address: CANTOR COLBURN LLP - IBM FISHKILL, 20 Church Street, 22nd Floor, Hartford, CT, 06103, US

(73) Assignees: INTERNATIONAL BUSINESS MACHINES CORPORATION, Armonk, NY (US); INFINEON TECHNOLOGIES NORTH AMERICA CORP ("INFINEON"), San Jose, CA (US); SAMSUNG ELECTRONICS CO., LTD., Gyeonggi-do (KR)

(21) Appl. No.: 11/845,448

(22) Filed: Aug. 27, 2007

(51) Int. Cl. H01L 29/94; H01L 21/336

(52) U.S. Cl. 257/329; 438/268; 257/E29.345; 257/E21.409

(57) ABSTRACT

Disclosed herein is a semiconducting device comprising a gate stack formed on a surface of a semiconductor substrate; a vertical nitride spacer element formed on each vertical sidewall of the gate stack; a portion of the vertical nitride spacer overlying the semiconductor substrate; a silicide contact formed on the semiconductor substrate adjacent the gate stack, the silicide contact being in operative communication with drain and source regions formed in the semiconductor substrate; and an oxide spacer disposed between the vertical nitride spacer element and the silicide contact; the oxide spacer operating to minimize an undercut adjacent the vertical nitride spacer during an etching process.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND

This disclosure relates to a spacer-undercut filler, methods of manufacture thereof and articles comprising the same. More specifically, the present disclosure relates to complementary metal oxide semiconductor (CMOS) devices, and more particularly to a process and structure for forming a metal oxide semiconductor field effect transistor (MOSFET) implementing thin sidewall spacer geometries.

FIGS. 1(a)-1(e) depict cross-sectional views of a portion of a semiconductor device manufactured in accordance with current processing techniques. As shown in FIG. 1(a), a semiconductor device 10 is formed on a wafer. The device includes a substrate 12 and a patterned gate stack 15 formed thereon. Each patterned gate stack 15 may be formed of a gate material such as polycrystalline silicon, for example, and as is known, the gate 15 is formed on a thin gate dielectric layer 20 previously formed on top of the substrate 12. Prior to the formation of low resistivity cobalt, titanium, or nickel silicide contacts with active device regions 16, 18 and the gate 15 of the semiconductor device 10, thin nitride spacers are first formed on each gate sidewall. As shown in FIG. 1(a), a dielectric etch stop layer 25, ranging from about 10 to about 300 Angstroms in thickness, specifically about 50 to about 150 Angstroms, is first deposited on the thin gate oxide layer 20 over the substrate surfaces and the patterned gate stack 15. While this dielectric etch stop prevents recessing of the substrate during reactive ion etching (RIE) of the spacer, it has the disadvantage of being susceptible to removal or undercut during the extensive preclean that is performed prior to silicide formation.

Then, as shown in FIG. 1(b), an additional dielectric layer 30 is deposited on the patterned gate stack and active device regions. This additional dielectric layer generally comprises a nitride material.

As shown in FIG. 1(c), a RIE process is performed, resulting in the formation of vertical nitride spacers 35a, 35b on each gate wall. Prior to metal deposition, which may be titanium, cobalt or nickel, a lengthy oxide strip process is performed to prepare the surface for the silicide formation. This oxide strip is crucial to achieving a defect free silicide. However, as illustrated in FIG. 1(d), the problem with this lengthy oxide strip is that the dielectric etch stop beneath the spacers 25 becomes severely undercut at regions 40a, 40b. The resultant oxide loss or undercut gives rise to the following problems: 1) the barrier nitride layer 50 that is ultimately deposited, as shown in FIG. 1(e), will be in contact with the gate dielectric edge 17, thus degrading gate dielectric reliability; 2) the silicide in the source/drain regions 60a,b (not shown) may come into contact with the gate dielectric at the gate conductor edge, which would create a diffusion to gate short); and, 3) the degree of undercut will vary significantly from lot to lot. These aforementioned problems are particularly acute for transistors with thin spacer geometries.

Thin sidewall spacer geometries are becoming important for high performance MOSFET design. Thin spacers permit the silicide to come into close proximity to the extension edge near the channel, thereby decreasing MOSFET series resistance and enhancing drive current. The implementation of a spacer etch process (specifically RIE) benefits substantially from an underlying dielectric layer (typically oxide) beneath the nitride spacer film. This dielectric serves as an etch stop for the nitride spacer RIE. Without this etch stop in place, the spacer RIE would create a recess in the underlying substrate, degrading the MOSFET series resistance, and in the case of thin SOI substrates, reducing the amount of silicon available for the silicide process.

In order to avoid the problems associated with thin spacer geometries on thin SOI, it would be extremely desirable to provide a method for avoiding the oxide undercut when performing the oxide removal step during the pre-silicide clean.

### SUMMARY

Disclosed herein is a semiconducting device comprising a gate stack formed on a surface of a semiconductor substrate; a vertical nitride spacer element formed on each vertical sidewall of the gate stack; a portion of the vertical nitride spacer overlying the semiconductor substrate; a silicide contact formed on the semiconductor substrate adjacent the gate stack, the silicide contact being in operative communication with drain and source regions formed in the semiconductor substrate; and an oxide spacer disposed between the vertical nitride spacer element and the silicide contact; the oxide spacer operating to minimize an undercut adjacent the vertical nitride spacer during an etching process.

Disclosed herein too is a method comprising disposing a gate stack upon a semiconductor substrate; disposing a vertical nitride spacer element on each vertical sidewall of the gate stack; a portion of the vertical nitride spacer overlying the semiconductor substrate; disposing a silicide contact on the semiconductor substrate adjacent the gate stack; and disposing an oxide spacer between the vertical nitride spacer element and the silicide contact; the oxide spacer operating to minimize an undercut adjacent the vertical nitride spacer during an etching process.

### BRIEF DESCRIPTION OF FIGURES

FIGS. 1A through 1E are cross-sectional views showing the CMOS processing steps according to a prior art method; and

FIGS. 2A through 2H are cross-sectional views showing the basic processing steps according to a first embodiment of the present invention.

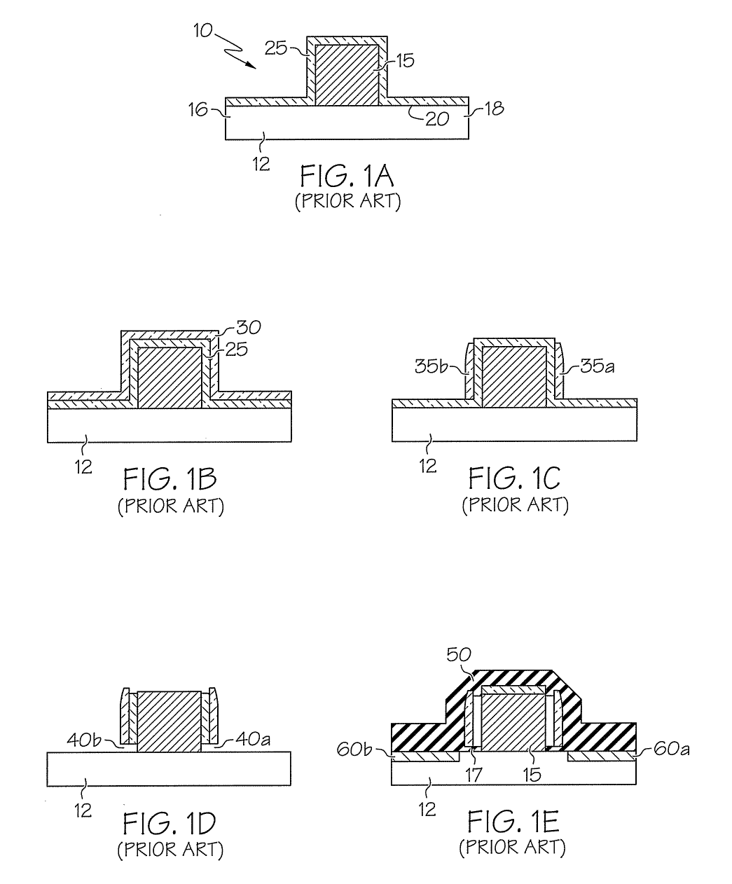

### DETAILED DESCRIPTION

Disclosed herein is a method of maintaining a continuous layer of oxide under a nitride spacer in a complementary metal oxide semiconductor (CMOS) device. The method advantageously comprises depositing a layer of conformal oxide, after the silicidation process, to fill the nitride spacer undercut. A subsequent RIE etch removes all oxide deposited on the sidewall of the nitride spacer, but the presence of the layer of conformal oxide prevents the development of any further spacer undercut. The filled oxide protects the substrate during lengthy oxide strips and spacer proximity technology (SPT) processes and prevents or minimizes severe junction leakage and subsequent device degradation.

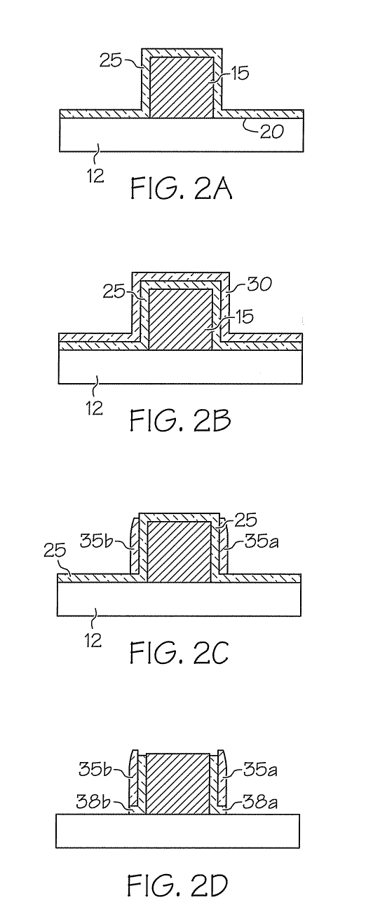

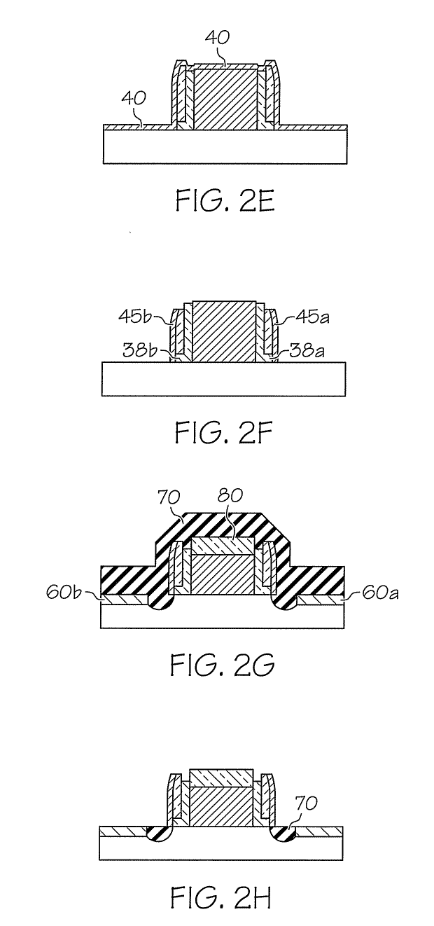

FIG. 2A, depicts an initial structure used in the present invention. Specifically, the initial structure shown in FIG. 2A comprises a semiconductor substrate 12 having a patterned gate stack 15 formed on portions of the semiconductor substrate. Each patterned gate stack includes a gate dielectric 20, gate conductor 15 formed atop the gate dielectric, and an additional dielectric etch stop material atop the gate conductor and substrate regions.

The structure shown in FIG. 2A is comprised of materials well known in the art, and it is fabricated utilizing processing steps that are also well known in the art. For example, semiconductor substrate 12 may comprise any semiconducting material including, but not limited to: Si, Ge, SiGe, GaAs, InAs, InP, and all other group III/V semiconductor compounds. Semiconductor substrate 12 may also include a layered substrate comprising the same or different semiconducting material, e.g., Si/Si or Si/SiGe, silicon-on-insulator (SOI), strained silicon, or strained silicon on insulator. The substrate may be of n- or p-type (or a combination thereof) depending on the desired devices to be fabricated.

Additionally, the semiconductor substrate 12 may contain active device regions, wiring regions, isolation regions or other like regions that are generally present in CMOS devices. For clarity, these regions are not shown in the drawings, but are nevertheless meant to be included within region 12. In two exemplary embodiments, the semiconductor substrate 12 is comprised of Si or SOI. With an SOI substrate, the CMOS device is fabricated on the thin Si layer that is present above a buried oxide (BOX) region.

A layer of gate dielectric material 20, such as an oxide, nitride, oxynitride, high-K material, or any combination and multilayer thereof, is then formed on a surface of semiconductor substrate 12 utilizing a thermal growing process such as oxidation, nitridation, plasma-assisted nitridation, oxynitridation, or alternatively by utilizing a deposition process such as chemical vapor deposition (CVD), plasma-assisted CVD, evaporation or chemical solution deposition, or the like, or a combination comprising at least one of the foregoing processes.

After forming gate dielectric 20 on the semiconductor substrate 12, a gate conductor 15 is formed on top of the gate dielectric. The term “gate conductor” as used herein denotes a conductive material, a material that can be made conductive via a subsequent process such as ion implantation or silicidation, or any combination thereof. The gate is then patterned utilizing conventional lithography and etching processes. Next, a dielectric etch stop layer 25 is formed on top of the patterned gate conductor. The dielectric etch stop or capping layer 25 is deposited atop the substrate 12 and gate stack 15. In an exemplary embodiment, the capping layer 25 is an oxide, having a layer thickness of about 10 Angstroms to about 300 Angstroms, and formed utilizing deposition processes such as, CVD, plasma-assisted CVD (PECVD), or ozone-assisted CVD, or the like, or a combination comprising at least one of the foregoing processes. Alternatively, a thermal growing process such as oxidation may be used in forming the dielectric capping layer 25. Exemplary oxides are SiO₂, ZrO₂, Ta₂O₅, HfO₂, Al₂O₃, or a combination comprising at least one of the foregoing oxides.

Next, and as illustrated in FIGS. 2B and 2C, spacer elements 35a, 35b are formed on the gate sidewalls. Spacer formation begins with the deposition of a nitride film 30 over the dielectric etch stop layer on the patterned gate stack, the gate sidewalls, and the substrate surfaces. The spacer thickness is about 700 Angstroms or less, specifically about 500 Angstroms or less. It is understood that these thickness values are exemplary and that other thickness regimes are also contemplated. The composition of the nitride layer can represent any suitable stoichiometry or combination of nitrogen and silicon. The deposition process can include PECVD, rapid thermal CVD (RTCVD), or low pressure CVD (LPCVD). After depositing the nitride layer 30 (via chemical vapor deposition or a similar conformal deposition process) on the structure shown in FIG. 2A, the vertical gate wall spacers 35a, 35b are then formed using a highly directional, anisotropic spacer etch, such as RIE. The nitride layer is etched, selective to the underlying dielectric etch stop layer 25, to leave the vertical nitride spacers layer 35a, 35b.

The key elements of the process are now shown in FIG. 2D-2F, whereby after spacer formation, the dielectric etch stop layer 25 remaining on the substrate 12 is first removed by an oxide etch process. This etch can be either dry (RIE or CDE) or wet. In FIG. 2D, there is depicted the RIE example for removing the remaining dielectric etch stop layer 25 save for a small portion of cap dielectric underlying the vertical nitride spacers.

In an optional embodiment, once the dielectric RIE is complete, as shown in FIG. 2D, the edges of the dielectric etch stop edges 38a, 38b under the vertical spacers, i.e., edges 38a, 38b, may be flush with the vertical edge of the spacer. This however is not necessary, and in another optional embodiment, the edges of the dielectric etch stop edges 38a, 38b under the vertical spacers, i.e., edges 38a, 38b, may not be flush with the vertical edge of the spacer.

Next, as shown in FIG. 2E, a thin nitride “plug” layer 40 is deposited over the remaining structure including the exposed gate and substrate surfaces. Preferably the thin nitride plug is 100 Angstroms or less in thickness and may include Si₃N₄, SiₓN_{y}, carbon-containing SiₓN_{y}, an oxynitride, a carbon-containing oxynitrides, or the like, or a combination comprising at least one for the foregoing nitrides. After deposition, the nitride “plug” layer 40 is etched using an anisotropic dry etch which removes the plug layer from the substrate surfaces and the top of the gate, as shown in FIG. 2F. As a result of this process, thin vertical nitride portions 45a, 45b remain that function to seal the respective underlying dielectric etch stop edges 38 a, 38b. In one embodiment, the anisotropic dry etch may be used to remove the thin vertical nitride portions 45a, 45b completely.

If CDE is used instead of RIE to etch the dielectric etch stop layer, the edge of the etch stop may be slightly recessed with respect to the vertical spacer edge. In this case, a wet etch may be used to remove the nitride “plug” layer from the substrate surfaces and the top of the gate, leaving behind a nitride “plug” to block the dielectric etch stop from subsequent lateral etching.

As shown in FIG. 2G, with spacers and nitride plug layers in place, it is understood that source/drain regions (not shown) may be formed by techniques, such as, for example, ion implantation into the surface of semiconductor substrate 12 utilizing an ion implantation process. It is understood, however, that at any point during the process, source/drain regions may be formed. Further, it is noted that at this point, it is also possible to implant dopants within the gate material. Various ion implantation conditions may be used in forming the deep source/drain regions within the substrate. In one embodiment, the source/drain regions may be activated at this point using activation annealing conditions. However, it is generally desirable to delay the activation of the source/drain regions until after shallow junction regions have been formed in the substrate.

In one optional embodiment, prior to the metal deposition for silicide formation, a series of wet cleans, dry cleans, or other physical cleaning techniques, may be implemented to remove contaminants such as: resist residuals, any remaining oxides formed during plasma cleans/strips, implant residuals, metals, and particles from the surface of the silicon wafer.

Silicide contacts 60a, 60b may be formed on portions of the semiconductor substrate 12 for contact with the respective source/drain regions. Specifically, the silicide contacts may be formed utilizing a silicidation process that includes the steps of depositing a layer of refractory metal, such as Ti, Ni, Co, or metal alloy on the exposed surfaces of the semiconductor substrate, annealing the layer of refractory metal under conditions that are capable of converting the refractory metal layer into a refractory metal silicide layer, and, if needed, removing any un-reacted refractory metal from the structure that was not converted into a silicide layer. Note that because of the nitride spacers and nitride plug, the silicide contacts may be self-aligned to any deep junction vertical edge present in the underlying substrate.

Following this a thin layer of low temperature oxide 70 may be disposed upon the entire exposed surface of the remaining structure. This thin layer of low temperature oxide is termed the conformal oxide layer and is generally deposited to prevent the undercut that occurs under the nitride layer when a lengthy oxide etch and post SPT etch is conducted. The low temperature oxide layer 70 generally comprises SiO₂, ZrO₂, Ta₂O₅, HfO₂, Al₂O₃, or a combination comprising at least one of the foregoing oxides.

The oxide layer 70 has a layer thickness of about 10 Angstroms to about 300 Angstroms. The oxide layer 70 is formed utilizing deposition processes such as, CVD, plasma-assisted CVD (PECVD), or ozone-assisted CVD, or the like, or a combination comprising at least one of the foregoing processes.

Following this, a lengthy oxide strip may be performed as depicted in FIG. 2H as part of the subsequent silicide preclean without the creation of an oxide undercut in the etch stop layer or under the nitride spacer. As can be seen in the FIG. 2H, a portion of the thin layer of low temperature oxide 70 is disposed in the region between the silicide layer and the nitride spacer to prevent the formation of the undercut during the lengthy oxide strip and subsequent stress proximity processes. This portion of the thin layer of low temperature oxide 70 disposed in the region between the silicide layer and the nitride spacer is termed an oxide spacer.

After the lengthy oxide strip, an isotropic nitride etch may be used to remove any remaining nitride. A WN or WP nitride deposition process may be conducted to for improvement of device performance by stress enhancement. WN is tensile nitride that is used on nFET and WP is the compressive nitride that is used on pFET for improvement of device performance.

As noted above, the deposition of the low temperature oxide layer 70 is advantageous in that it prevents the formation of an undercut, which minimizes or eliminates the junction leakage current and device degradation.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A semiconducting device comprising:
a gate stack formed on a surface of a semiconductor substrate;
a vertical nitride spacer element formed on each vertical sidewall of the gate stack; a portion of the vertical nitride spacer overlying the semiconductor substrate;
a silicide contact formed on the semiconductor substrate adjacent the gate stack, the silicide contact being in operative communication with drain and source regions formed in the semiconductor substrate; and
an oxide spacer disposed between the vertical nitride spacer element and the silicide contact; the oxide spacer operating to minimize an undercut adjacent the vertical nitride spacer during an etching process.

2. The semiconducting device of claim 1, further comprising a gate dielectric layer disposed atop the semiconductor substrate.

3. The semiconducting device of claim 1, wherein the semiconductor substrate comprises silicon, germanium, silicon-germanium, gallium-arsenide (GaAs), indium-arsenide (InAs), indium-phosphorus (InP), Si/Si, Si/SiGe, silicon-on-insulators, or a combination comprising at least one of the foregoing.

4. The semiconducting device of claim 1, wherein the oxide spacer comprises an oxide selected from the group consisting of SiO₂, ZrO₂, Ta₂O₅, HfO₂, Al₂O₃, and a combination comprising at least one of the foregoing oxides.

5. An article comprising the semiconducting device of claim 1.

6. A method comprising:
disposing a gate stack upon a semiconductor substrate;
disposing a vertical nitride spacer element on each vertical sidewall of the gate stack; a portion of the vertical nitride spacer overlying the semiconductor substrate;
disposing a silicide contact on the semiconductor substrate adjacent the gate stack; and
disposing an oxide spacer between the vertical nitride spacer element and the silicide contact; the oxide spacer operating to minimize an undercut adjacent the vertical nitride spacer during an etching process.

7. The method of claim 6, wherein the disposing of the oxide spacer between the vertical nitride spacer element and the silicide contact comprises:
disposing a layer of oxide upon exposed surfaces of the semiconductor substrate, the gate stack and the vertical nitride spacer elements;
etching the layer of oxide from the exposed surfaces of the semiconductor substrate, the gate stack and the vertical nitride spacer elements and retaining a portion of the layer of oxide that is disposed between the vertical nitride spacer element and the silicide contact.

8. The method of claim 6, further comprising performing a spacer proximity etch.

9. The method of claim 6, wherein the oxide is a low temperature oxide selected from the group consisting of SiO₂, ZrO₂, Ta₂O₅, HfO₂, Al₂O₃, and a combination comprising at least one of the foregoing oxides.

10. The method of claim 6, wherein the low temperature oxide spacer has a thickness of about 10 Angstroms to about 300 Angstroms.

11. An article manufactured by the method of claim 6.
